(19) United States
(12) Patent Application Publication
(10) Pub. No.: US 2015/0236699 A1
(43) Pub. Date: Aug. 20, 2015

(54) INPUT BUFFER CIRCUIT, METHOD, AND INTEGRATED CIRCUIT

(71) Applicants: Yanfang Li, Beijing (CN); Lei Huang, Beijing (CN); Zhaohong Li, Beijing (CN)

(72) Inventors: Yanfang Li, Beijing (CN); Lei Huang, Beijing (CN); Zhaohong Li, Beijing (CN)

(21) Appl. No.: 14/622,616

(22) Filed: Feb. 13, 2015

(30) Foreign Application Priority Data
Feb. 14, 2014 (CN) 201410062074.8

(51) Int. Cl. H03K 19/0175; H03K 19/094

(52) U.S. Cl. CPC H03K 19/017509; H03K 19/09407

(57) ABSTRACT

This document discusses, among other things, an input buffer circuit, an input buffer method, and an integrated circuit, the input buffer circuit raising, using a potential raising device, a potential of a first reference ground to a potential of a second reference ground of an input stage, and improving a trigger voltage of the input stage. After the input stage is triggered and outputs a first buffer signal, an output stage transforms the potential of the second reference ground of the first buffer signal back to the potential of the first reference ground, and outputs a second buffer signal.

### CLAIM OF PRIORITY

The application claims the benefit of priority under 35 U.S.C. §119(a) to Ricky Li et al. CN Application No. 201410062074.8, filed on Feb. 14, 2014, which is hereby incorporated by reference in its entirety.

### TECHNICAL FIELD

The present invention relates to signal detection technology, and particularly relates to an input buffer circuit, method, and integrated circuit.

### BACKGROUND

At present, most terminal devices are equipped with interfaces for connection with external devices, which interface facilitates access and use of the external devices. After an external device is inserted into the interface of a terminal device, the terminal device needs to detect and identify, at the interface, the inserted peripheral device. Since the interface of the terminal device may support a plurality of types of external devices, the terminal device can identify the inserted peripheral devices by using different signals generated after the external devices are inserted into the interface.

Under normal circumstances, the interface of the terminal device needs to accurately identify, by using an input buffer circuit, the signal generated after an external device is inserted to the interface thereof. However, if a signal having a low voltage is capable of triggering the input buffer circuit, it is common that when an interference signal is present, the input buffer circuit may be mistakenly triggered.

### OVERVIEW

To solve the technical problem present in the prior art, embodiments of the present invention provide an input buffer circuit, an input buffer method, and an integrated circuit.

In an example, an input buffer circuit includes a potential raising device, an input stage, and an output stage. The potential raising device is configured to raise a potential of a first reference ground to a potential of a second reference ground of the input stage, and raise a trigger voltage of the input stage. The input stage is configured to be triggered upon receiving a trigger signal reaching the trigger voltage, and output a first buffer signal to the output stage. The output stage is configured to receive the first buffer signal output by the input stage, transform the potential of the second reference ground of the first buffer signal back to the potential of the first reference ground, and output a second buffer signal.

An example input buffer method includes raising a potential of a first reference ground to a potential of a second reference ground of an input stage by using a potential raising device, and raising a trigger voltage of the input stage, and after the input stage is triggered and outputs a first buffer signal, transforming, by an output stage, the potential of the second reference ground of the first buffer signal back to the potential of the first reference ground, and outputting a second buffer signal.

An example integrated circuit includes an input buffer circuit, comprising a potential raising device, an input stage, and an output stage, wherein the potential raising device is configured to raise a potential of a first reference ground to a potential of a second reference ground of the input stage, and raise a trigger voltage of the input stage, the input stage is configured to be triggered upon receiving a trigger signal reaching the trigger voltage, and output a first buffer signal to the output stage, and the output stage is configured to receive the first buffer signal output by the input stage, transform the potential of the second reference ground of the first buffer signal back to the potential of the first reference ground, and output a second buffer signal.

According to the input buffer circuit, the input buffer method, and the integrated circuit provided herein, the input buffer circuit raises, by using a potential raising device, a potential of a first reference ground of an input stage to a potential of a second reference ground, and improves a trigger voltage of the input stage. After the input stage is triggered and outputs a first buffer signal, an output stage transforms the potential of the second reference ground of the first buffer signal back to the potential of the first reference ground, and outputs a second buffer signal. In this way, the trigger voltage of the input buffer circuit may be improved, the input buffer circuit may be prevented from being mistakenly triggered due to an interference signal, and accuracy of external device access detection by using the input buffer circuit is improved.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a schematic structural diagram of an input buffer circuit.

FIG. 2 is a schematic diagram of element connection of the input buffer circuit.

FIG. 3 is a simulation diagram of triggering of an input buffer circuit in the prior art;

FIG. 4 is a simulation diagram of triggering of the input buffer circuit.

FIG. 5 is a schematic diagram illustrating element connection of an input buffer circuit which outputs a buffer signal having a polarity reverse to an input polarity.

FIG. 6 is a schematic diagram illustrating a scenario where an external plug is inserted into an interface having an input buffer circuit.

FIG. 7 is a schematic flowchart of an input buffer method.

### DETAILED DESCRIPTION

This document discusses, among other things, raising a potential of a first reference ground to a potential of a second reference ground of an input stage by using a potential raising device, and raising a trigger voltage of the input stage, and after the input stage is triggered and outputs a first buffer signal, transforming, by an output stage, the potential of the second reference ground of the first buffer signal back to the potential of the first reference ground, and outputting a second buffer signal.

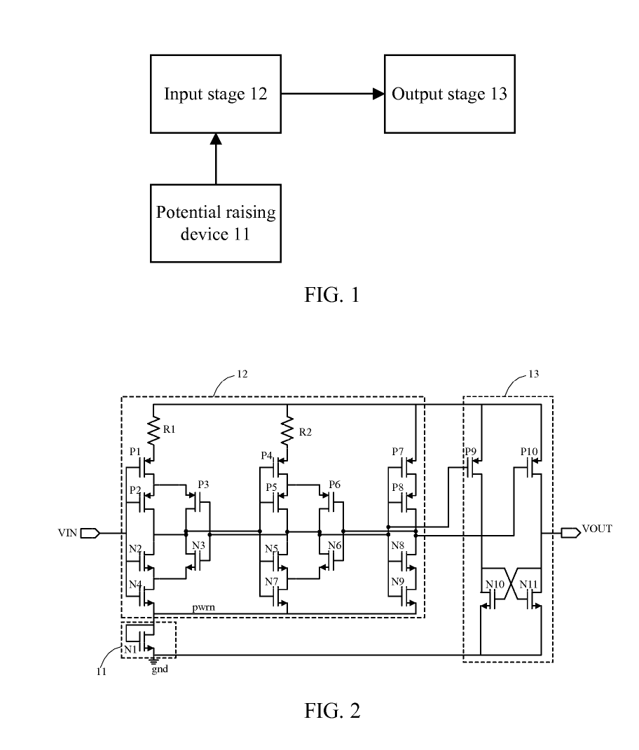

As illustrated in FIG. 1, an input buffer circuit includes a potential raising device 11, an input stage 12, and an output stage 13. The potential raising device 11 raises a potential of a first reference ground to a potential of a second reference ground of the input stage 12, and improves a trigger voltage of the input stage 12, and the input stage 12 is triggered upon receiving a trigger signal reaching the trigger voltage, and outputs a first buffer signal to the output stage 13. The output stage 13 can receive the first buffer signal output by the input stage 12, transforms the potential of the second reference ground of the first buffer signal back to the potential of the first reference ground, and outputs a second buffer signal.

The potential raising device 11 can include a transistor having a constant voltage drop, for example, an n-type metal-oxide-semiconductor (NMOS), a diode or the like, which can be serially connected between the input stage 12 and the first reference ground and is capable of raising the potential of the first reference ground by the voltage drop to the potential of the second reference ground.

The potential raising device 11 is a first NMOS N1, wherein a source of the first NMOS N1 is connected to a first reference ground gnd, a gate of the first NMOS N1 is connected to a drain of the first NMOS N1, and is connected to a ground terminal of the input stage 12 as a second reference ground pwrn.

The input stage 12 can include a first p-type metal-oxide-semiconductor (PMOS) P1 to an eight PMOS P8, a second NMOS N2 to a ninth NMOS N9, a first resistor R1, and a second resistor R2. In an example, one terminal of the first resistor R1 is connected to a power supply voltage VDD, and the other terminal of the first resistor is connected to a source of the first PMOS P1. A gate of the first PMOS Pl, a gate of the second PMOS P2, a gate of the second NMOS N2, and a gate of the fourth NMOS N4 can be connected, serving as an input terminal VIN to receive the trigger signal. A drain of the first PMOS P1 can be connected to a source of the second PMOS P2 and a source of the third PMOS P3. A drain of the second PMOS P2 can be connected to a drain of the third PMOS P3, a drain of the second NMOS N2, a drain of the third NMOS N3, a gate of the fourth PMOS P4, a gate of the fifth PMOS P5, a gate of the fifth NMOS N5, and a gate of the seventh NMOS N7. A source of the second NMOS N2 can be connected to a drain of the fourth NMOS N4 and a source of the third NMOS N3. A source of the fourth NMOS N4 can be connected to the second reference ground pwrn. A gate of the third PMOS P3 can be connected to a gate of the third NMOS N3, a drain of the fifth PMOS P5, a drain of the fifth NMOS N5, a drain of the sixth PMOS P6, a drain of the sixth NMOS N6, a gate of the seventh PMOS P7, a gate of the eighth PMOS P8, a gate of the eighth NMOS N8, a gate of the ninth NMOS N9, and the output stage 13.

In an example, one terminal of the second resistor R2 is connected to the power supply voltage VDD, and the other terminal of the second resistor R2 is connected to a source of the fourth PMOS P4. A drain of the fourth PMOS P4 is connected to a source of the fifth PMOS P5 and a source of the sixth PMOS P6. A source of the fifth NMOS N5 is connected to a drain of the seventh NMOS N7 and a source of the sixth NMOS N6. A source of the seventh NMOS N7 is connected to the second reference ground pwrn. A gate of the sixth PMOS P6 is connected to a gate of the sixth NMOS N6, a drain of the eighth PMOS P8, a drain of the eighth NMOS N8, and the output stage 13. A source of the seventh PMOS P7 is connected to the power supply voltage VDD. A drain of the seventh PMOS P7 is connected to a source of the eighth PMOS P8, a source of the eighth NMOS N8 is connected to a drain of the ninth NMOS N9, and a source of the ninth NMOS N9 is connected to the second reference ground pwrn.

The input stage 13 can include a ninth PMOS P9 to a tenth PMOS P10, and a tenth NMOS N10 to an eleventh NMOS N11. In an example, a gate of the ninth PMOS P9 is connected to the gate of the seventh PMOS P7, the gate of the eighth PMOS P8, the gate of the eighth NMOS N8, and the gate of the ninth NMOS N9 of the input stage 12. A source of the ninth PMOS P9 is connected to the power supply voltage VDD. A drain of the ninth PMOS P9 is connected to a drain of the tenth NMOS N10 and a gate of the eleventh NMOS N11. A gate of the tenth PMOS P10 is connected to the drain of the eighth PMOS P8 and the drain of the eighth NMOS N8 of the input stage 12. A source of the tenth PMOS P10 is connected to the power supply voltage VDD. A drain of the tenth PMOS P10 is connected to a gate of the tenth NMOS N10 and a drain of the eleventh NMOS N11 and serves as an output terminal VOUT. A source of the tenth NMOS N10 is connected to the first reference ground gnd, and a source of the eleventh NMOS N11 is connected to the first reference ground gnd.

In the input buffer circuit as illustrated in FIG. 2, the potential of the second reference ground pwrn can be the sum of the potential of the first reference ground gnd and a gate-source voltage Vgs of the first NMOS N1, and correspondingly, the voltage of the initial trigger signal may trigger the input buffer circuit only after the gate-source voltage Vgs of the first NMOS N1 is improved.

For example, in the prior art, the voltage of the trigger signal of the input buffer circuit is 1.0 V. As illustrated in FIG. 3, the solid line in FIG. 3 denotes the voltage of a simulated interference signal, and the dashed line denotes the voltage of an output terminal of the input buffer circuit in the prior art.

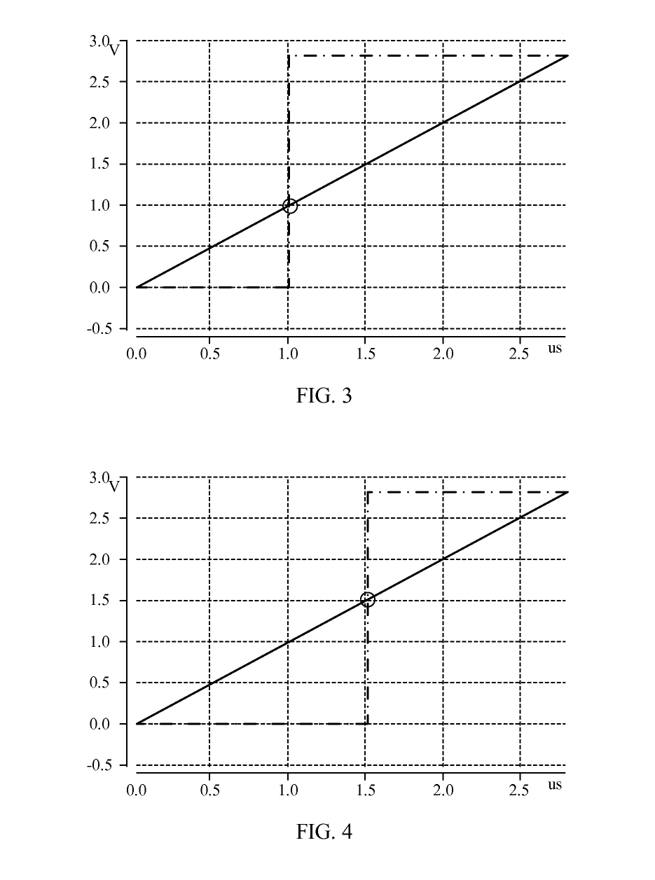

In the prior art, when the input buffer circuit is subjected to an interference signal having a voltage reaching 1.0 V, the output of the output terminal changes from a low level to a high level, i.e., the output terminal is triggered and then outputs a high level buffer signal. In an example, in the buffer circuit described herein, as illustrated in FIG. 4, the solid line in FIG. 4 denotes the voltage of a simulated interference signal, and the dashed line denotes the voltage of an output terminal of the input buffer circuit according to various embodiments.

When the voltage of interference signal is 1.5 V, the output of the output terminal VOUT changes from a low level to a high level, and, in an example, the output terminal is triggered. However, when the voltage of the interference signal is less than 1.5 V, the output of the output terminal VOUT is constantly a low level, and, in an example, the output terminal is not triggered. In the embodiments of the present invention, the trigger threshold is improved by about 0.5 V for the input buffer circuit as compared against the input buffer circuit in the prior art.

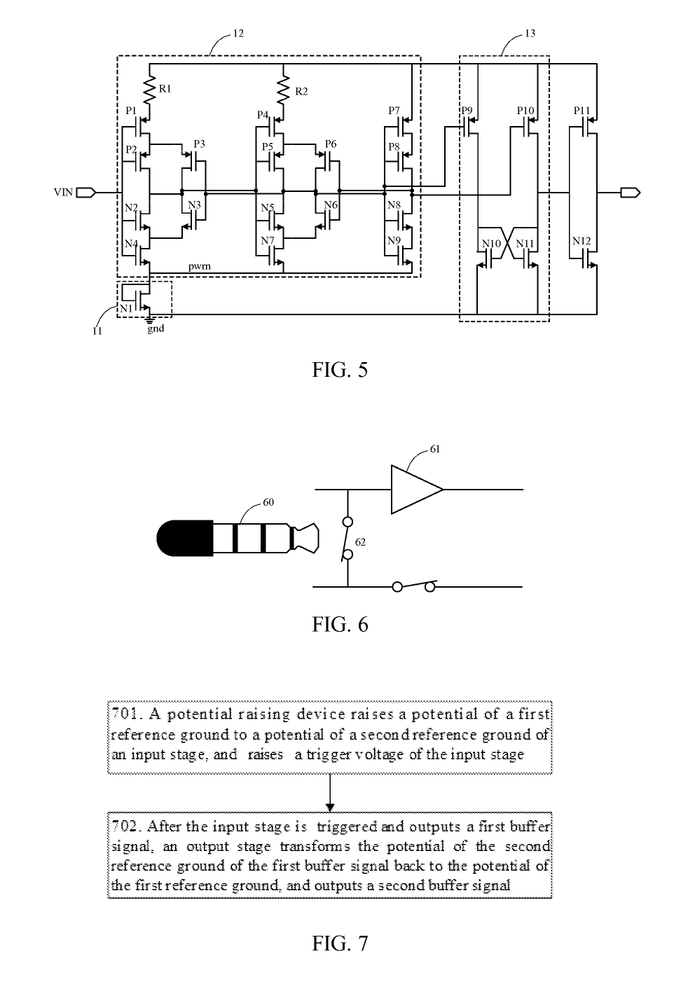

When the input buffer circuit as illustrated in FIG. 2 needs to output a buffer signal having a polarity reverse to an input polarity, as illustrated in FIG. 5, a signal inverter may be connected to the output terminal VOUT of the output stage 13. The signal inverter comprises an eleventh PMOS P11 and a twelfth NMOS N12, wherein a source of the eleventh PMOS P11 is connected to the power supply voltage VDD, a gate of the eleventh PMOS P11 is connected to a drain of the tenth PMOS P10 and a gate of the twelfth NMOS N12, a drain of the eleventh PMOS P11 is connected to a drain of the twelfth NMOS N12 and serves as a final output terminal, and a source of the twelfth NMOS N12 is connected to the first reference ground gnd.

FIG. 6 is a schematic diagram illustrating the scenario where an external plug 60 is inserted into an interface having an input buffer circuit 61 in practice, wherein the input buffer circuit 61 can include the input buffer circuit as illustrated in FIG. 1 or 2. When the external plug 60 is inserted into the interface, the scenario where a switch 62 can be closed, and thus an interference signal about ±1.414 V can be input to the input buffer circuit 61. Since the trigger voltage of the input buffer circuit 61 has been improved, the input buffer circuit 61 may not be triggered and no buffer signal may be mistakenly generated.

Based on the above input buffer circuit, an embodiment provides an input buffer method. As illustrated in FIG. 7, the method comprises the following steps:

Step 701: A potential raising device raises a potential of a first reference ground to a potential of a second reference ground of an input stage, and improves a trigger voltage of the input stage.

A potential raising device can be serially connected between the input stage and the first reference ground, wherein the potential raising device is typically a transistor having a constant voltage drop, for example, an NMOS, a diode or the like, which is capable of raising the potential of the first reference ground by the voltage drop to the potential of the second reference ground. In this way, the trigger voltage of the input stage can also be improved by the voltage drop.

Step 702: After the input stage is triggered and outputs a first buffer signal, an output stage transforms the potential of the second reference ground of the first buffer signal back to the potential of the first reference ground, and outputs a second buffer signal.

Based on the above input buffer circuit, an embodiment provides an integrated circuit, including the input buffer circuit comprises a potential raising device 11, an input stage 12, and an output stage 13.

In an example, the potential raising device 11 raises a potential of a first reference ground to a potential of a second reference ground of the input stage 12, and improves a trigger voltage of the input stage 12. The input stage 12 is triggered upon receiving a trigger signal reaching the trigger voltage, and outputs a first buffer signal to the output stage 13. The output stage 13 receives the first buffer signal output by the input stage 12, transforms the potential of the second reference ground of the first buffer signal back to the potential of the first reference ground, and outputs a second buffer signal.

The potential raising device 11 can include a transistor having a constant voltage drop, for example, an NMOS, a diode or the like, which is serially connected between the input stage 12 and the first reference ground and is capable of raising the potential of the first reference ground by the voltage drop to the potential of the second reference ground.

According to the technical solutions provided herein, an input buffer circuit can raise, using a potential raising device, a potential of a first reference ground of an input stage to a potential of a second reference ground, improve a trigger voltage of the input stage, transform the potential of the second reference ground at an output stage back to the potential of the first reference ground, and output a buffer signal. In this way, the input buffer circuit may be prevented from being mistakenly triggered due to an interference signal, and accuracy of external device access detection by using the input buffer circuit is improved.

Additional Notes and Examples

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A buffer circuit for identifying an external device, comprising:
an input buffer circuit configured to receive an input signal of the external device, and buffer the input signal to provide a first buffer signal when the input signal reaches the raised trigger voltage;
an output buffer circuit coupled to a reference voltage, and configured to receive the first buffer signal from the input buffer circuit, and buffer the first buffer signal to provide a second buffer signal; and
a voltage raising device configured to be coupled between the input buffer circuit and the reference voltage to obtain the raised trigger voltage.

2. The buffer circuit according to claim 1, wherein the voltage raising device comprises a transistor or a resistor.

3. The buffer circuit according to claim 2, wherein the transistor comprises an n-type metal-oxide-semiconductor (NMOS) or a diode.

4. The buffer circuit according to claim 1, wherein the input buffer circuit comprises at least one Schmitt trigger configured to receive the input signal.

5. The buffer circuit according to claim 1, wherein the input buffer circuit comprises a first inverter configured to output the first buffer signal.

6. The buffer circuit according to claim 1, wherein the output buffer circuit comprises a level shift coupled to the ground.

7. The buffer circuit according to claim 1, further comprising a second inverter, wherein the second inverter is coupled to the output buffer circuit to invert a polarity of the second buffer signal.

8. The buffer circuit according to claim 1, wherein the reference voltage comprises ground voltage.

9. A buffer method for identifying an external device, comprising:
receiving, by an input buffer circuit, an input signal of the external device;
buffering, by the input buffer circuit, the input signal and providing a first buffer signal to an output buffer circuit when a voltage of the input signal reaches the raised trigger voltage; and
buffering, by the output buffer circuit, the first buffer signal and outputting a second buffer signal.

10. The method according to claim 9, wherein the raised trigger voltage is provided by using a voltage raising device.

11. The method according to claim 10, wherein the voltage raising device comprises a transistor or a resistor.

12. The method according to claim 9, wherein the transistor comprises an n-type metal-oxide-semiconductor (NMOS) or a diode.

13. The method according to claim 9, further comprising:
inverting a polarity of the second buffer signal.

14. A device, comprising:
a switch configured to be closed when an external device is inserted;
a buffer circuit, coupled to the switch, for identifying the external device, the buffer circuit comprising:
an input buffer circuit configured to receive an input signal of the external device, and buffer the input signal to provide a first buffer signal when the input signal reaches the raised trigger voltage;
an output buffer circuit coupled to a reference voltage, and configured to receive the first buffer signal from the input buffer circuit, and buffer the first buffer signal to provide a second buffer signal; and
a voltage raising device configured to be coupled between the input buffer circuit and the reference voltage to obtain the raised trigger voltage.

15. The device according to claim 14, wherein the voltage raising device comprises a transistor or a resistor.

16. The device according to claim 15, wherein the transistor comprises an n-type metal-oxide-semiconductor (NMOS) or a diode.

17. The device according to claim 14, further comprising an inverter, wherein the inverter is coupled to the output buffer circuit to invert a polarity of the second buffer signal.

18. The device according to claim 14, wherein the reference voltage comprises ground voltage.
